(19) United States
(12) Patent Application Publication
(10) Pub. No.: US 2012/0192924 A1
(43) Pub. Date: Aug. 2, 2012

(54) MONOLITHIC INTEGRATION OF SUPER-STRATE THIN FILM PHOTOVOLTAIC MODULES

(75) Inventor: Bulent M. Basol, Manhattan Beach, CA (US)

(73) Assignee: Encoresolar, Inc., Fremont, CA (US)

(21) Appl. No.: 13/363,245

(22) Filed: Jan. 31, 2012

Related U.S. Application Data
(60) Provisional application No. 61/462,307, filed on Feb. 1, 2011.

(51) Int. Cl. H01L 31/05; H01L 31/18

(52) U.S. Cl. 136/249; 438/68; 257/E31.015

(57) ABSTRACT

An integrated structure for solar modules may be formed by deposition of a transparent conductive material layer on a transparent support, forming scribe lines through the transparent conductive material layer, depositing a semiconductor window layer, depositing a solar cell absorber layer, depositing a first conductive layer, making cuts through the layers to expose a top surface of the transparent conductive material layer, depositing a second conductive layer and making isolation scribes that separate back contacts of adjacent solar cells from each other. Alternatively, two conductive films may be used with high resistance plugs, thereby permitting optimization of functions. The first film may be selected to optimize good ohmic contact with the absorber layer and/or to present a high diffusion barrier, whereas the second conductive film may be selected to optimize good ohmic contact with the transparent conductive material layer.

### FIELD OF THE INVENTION

The present invention relates to fabrication of thin film photovoltaic modules such as CdTe modules.

### BACKGROUND OF THE INVENTION

Solar cells and modules are photovoltaic (PV) devices that convert sunlight energy into electrical energy. The most common solar cell material is silicon (Si). However, lower cost PV cells may be fabricated using thin film growth techniques that can deposit solar-cell-quality polycrystalline compound absorber materials on large area substrates using low-cost methods.

Group IIB-VIA compound semiconductors comprising some of the Group IIB (Cd, Zn, Hg) and Group VIA (O, S, Se, Te, Po) materials of the periodic table are excellent absorber materials for thin film solar cell structures. Especially CdTe has proved to be a material that can be used in manufacturing high efficiency solar panels at a cost below $1/W.

FIGS. 1A and 1B show two different structures employed in CdTe based solar cells. FIG. 1A is a “super-strate” structure, wherein the light enters the device through a transparent sheet that it is fabricated on. FIG. 1B depicts a “sub-strate” structure, wherein the light enters the device through a transparent conductive layer deposited over the CdTe absorber, which is grown over a substrate.

Referring to FIG. 1A, in a “super-strate” structure light enters the active layers of the device through a transparent sheet 11 and goes through a rectifying p-n junction before getting absorbed in a semiconductor absorber film. The transparent sheet 11 serves as the support on which the active layers are deposited. In fabricating the “super-strate” structure 10, a transparent conductive layer (TCL) 12 is first deposited on the transparent sheet 11. Then a junction partner layer 13, which is typically an n-type semiconductor, is deposited over the TCL 12. A CdTe absorber film 14, which is a p-type semiconductor film, is next formed on the junction partner layer 13 thus forming a p-n junction. Then an ohmic contact layer 15 is deposited on the CdTe absorber film 14, completing the solar cell. As shown by arrows 18, light enters this device through the transparent sheet 11. In the “super-strate” structure 10 of FIG. 1A, the transparent sheet 11 may be glass or a material (e.g., a high temperature polymer such as polyimide) that has high optical transmission (such as higher than 80%) in the visible spectra of the sun light. The TCL 12 is usually a transparent conductive oxide (TCO) layer comprising any one of; tin-oxide, cadmium-tin-oxide, indium-tin-oxide, and zinc-oxide which are doped to increase their conductivity. Multi layers of these TCO materials as well as their alloys or mixtures may also be utilized in the TCL 12. The junction partner layer 13 is typically a CdS layer, but may alternately be another compound layer such as a layer of CdZnS, ZnS, ZnSe, ZnSSe, CdZnSe, etc. The ohmic contact 15 is made of a highly conductive metal such as Mo, Ni, Cr, Ti, Al or a doped transparent conductive oxide such as the TCOs mentioned above. The rectifying junction, which is the heart of this device, is located near an interface 19 between the p-type CdTe absorber film 14 and the junction partner layer 13, which is n-type. It should be noted that the “super-strate” device structure of FIG. 1A may employ absorber layers other than or in addition to CdTe. These absorber layers include, but are not limited to, copper indium gallium selenide (sulfide) or CIGS(S), and other compound semiconductor materials.

In the “sub-strate” structure 17 of FIG. 1B, the ohmic contact layer 15 is first deposited on a sheet substrate 16, and then the CdTe absorber film 14 is formed on the ohmic contact layer 15. This is followed by the deposition of the junction partner layer 13 and the transparent conductive layer (TCL) 12 over the CdTe absorber film 14. As shown by arrows 18 in FIG. 1B, light enters this device through TCL 12. There may also be finger patterns (not shown) on the TCL 12 to lower the series resistance of the solar cell. The sheet substrate 16 does not have to be transparent in this case. Therefore, the sheet substrate 16 may comprise a sheet or foil of metal, glass or polymeric material.

For the manufacturing of high voltage PV modules, the solar cells need to be interconnected. For thin film PV technologies such interconnection is most commonly achieved through monolithic integration approaches. An example of a process flow for monolithic integration of a CdTe module is shown in FIG. 2. The first step in the manufacturing process of FIG. 2 is the deposition of a transparent conductive oxide layer 21 or TCO layer on a transparent sheet 20 such as glass. The transparent conductive oxide layer 21 is then scribed, typically by an infrared laser beam, to form several TCO strips 23 electrically isolated by laser scribes 22. Then a CdS/CdTe stack 24, comprising a CdS layer 24A and a CdTe layer 24B, is deposited over the TCO strips 23 and then scribed, typically by a green laser, which opens lines 25 through the CdS/CdTe stack 24. The lines 25 are next to and parallel to the laser scribes 22. The next step of the process is the deposition of a metallic top contact layer 26 over the whole structure so that the metallic top contact layer 26 makes low resistance ohmic contact to the top surface of the CdTe layer 24B and also fills the lines 25, electrically shorting to the TCO strips 23 at the bottom. The last step of the process involves scribing of the metallic top contact layer 26 and optionally the CdS/CdTe stack 24 and formation of device strips 28 separated by cuts 27. The device strips 28 comprise an active device region 29A and an interconnect region 29B. It should be noted that in the integrated module structure 30 of FIG. 2, adjacent device strips 28 are electrically connected in series, i.e. a top contact layer of one device strip is electrically connected to a bottom TCO strip of the adjacent device strip. It should also be noted that the top contact layer constitutes a (+) contact and the bottom TCO strip constitutes a (−) contact in this device structure.

Embodiments of the present inventions provide methods and device structures that yield higher quality monolithic integration of photovoltaic devices, which employ a “super-strate” structure.

### BRIEF DESCRIPTION OF THE DRAWINGS

FIG. 1A is a cross-sectional view of a prior-art CdTe solar cell with a “super-strate structure”.

FIG. 1B is a cross-sectional view of a prior-art CdTe solar cell with a “sub-strate structure”.

FIG. 2 shows a prior art process flow and integrated module structure.

FIG. 3A shows a layered structure comprising a scribed transparent conductive material layer, a semiconductor window layer, a solar cell absorber layer, and a first conductive layer formed over a transparent support.

FIG. 3B shows a structure resulting from further processing of the layered structure of FIG. 3A by making cuts in the three layers over the transparent conductive material layer, and depositing a second conductive layer.

FIG. 3C shows an integrated module structure obtained after the step of making isolation scribes in the structure of FIG. 3B.

FIG. 4A shows a stacked structure with parallel cuts comprising a transparent conductive film, a transparent junction formation layer, a PV absorber layer and a first conductive film, formed over a transparent support sheet.

FIG. 4B shows a structure resulting from further processing of the stacked structure of FIG. 4A by filling the parallel cuts with high resistance plugs and forming connection scribes.

FIG. 4C shows an integrated thin film module structure obtained after the step of depositing a second conductive film over the structure of FIG. 4B and forming isolation lines.

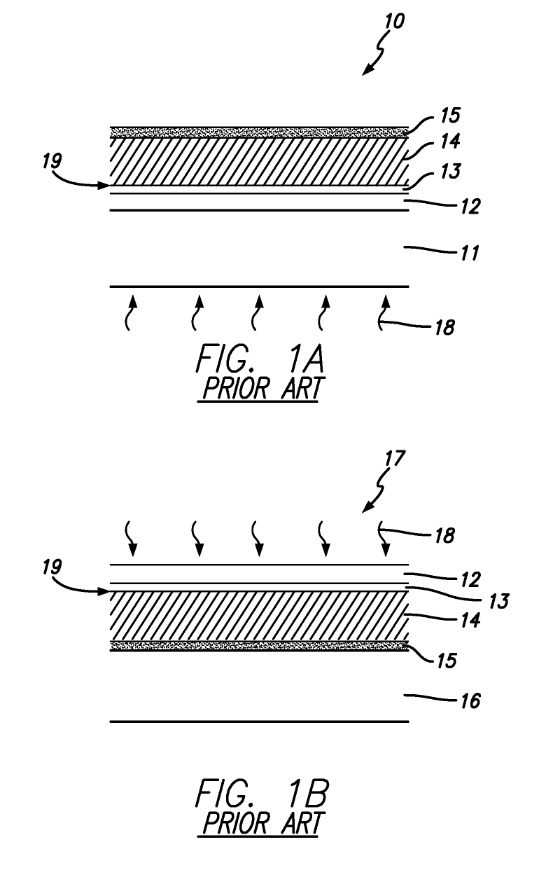

### DETAILED DESCRIPTION OF THE INVENTION

In general, embodiments of the present inventions form high performance monolithically integrated thin film photovoltaic modules, employing “super-strate” device structures. These embodiments will now be described using CdTe solar cells as an example. It should be noted that the embodiments and underlying principles disclosed herein are applicable to other solar modules using other absorber materials as long as the device structure is a “super-strate” type.

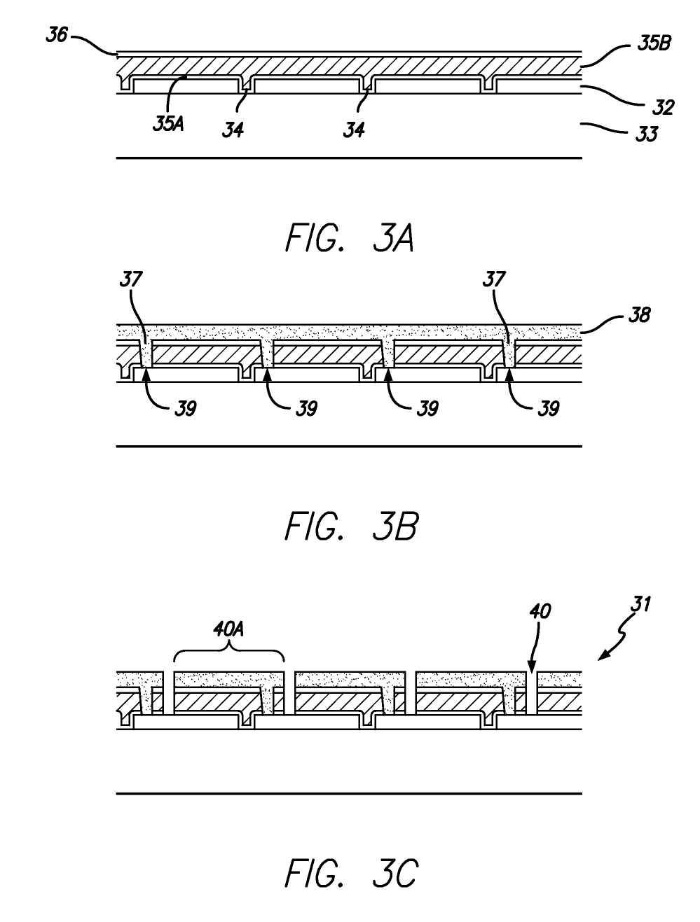

FIGS. 3A-3B show a process flow that results in an improved integrated module structure 31 with the resulting structure shown in FIG. 3C. As shown in FIG. 3A, the first step in the process is the deposition of a transparent conductive material layer 32 on a transparent support 33 which may be a sheet of glass or polymeric material. The transparent conductive material layer 32 is then processed, preferably by a laser beam, to form scribe lines 34. A semiconductor window layer (junction partner layer) 35A and a solar cell absorber layer 35B are then deposited as shown in FIG. 3A. A preferred material for the semiconductor window layer 35A is CdS and a preferred material for the solar cell absorber layer is a Group IIB-VIA compound film such as a CdTe film. After the deposition of the solar cell absorber layer 35B, a first conductive layer 36 is deposited on the solar cell absorber layer 35B. At this stage of the process a solar cell has been formed over the transparent support 33 since the first conductive layer 36 establishes a back ohmic contact to the absorber layer 35B. It should be noted that other well known process steps may be applied to the solar cell absorber layer 35B before the deposition of the first conductive layer 36. These well known processes include annealing the solar cell absorber layer 35B in presence of Cl and/or in an oxygen containing environment, doping the exposed surface of the solar cell absorber layer 35B with dopants such as Cu, and chemically etching the exposed surface of the solar cell absorber layer 35B before depositing the first conductive layer 36.

As shown in FIG. 3B, cuts 37 are then made in the stack comprising the first conductive layer 36, the solar cell absorber layer 35B and the semiconductor window layer 35A, wherein the cuts are deep enough to expose a top surface of the transparent conductive material layer 32 along the bottom of the cuts 37. A second conductive layer 38 is then deposited. The second conductive layer 38 makes physical and electrical contact to the top surface of the transparent conductive material layer 32 at the bottom of the cuts 37 at locations 39.

FIG. 3C shows the resulting integrated module structure 31 after isolation scribes 40 are made, cutting through at least the second conductive layer 38 and the first conductive layer 36, and optionally also cutting through the solar cell absorber layer 35B and optionally, through the semiconductor window layer 35A. The isolation scribes form regions which act as insulators and may be left unfiled or filled with an electrical insulator material. The scribes divide the module structure 31 into a plurality of stacks 40A, each separated by a scribe 40.

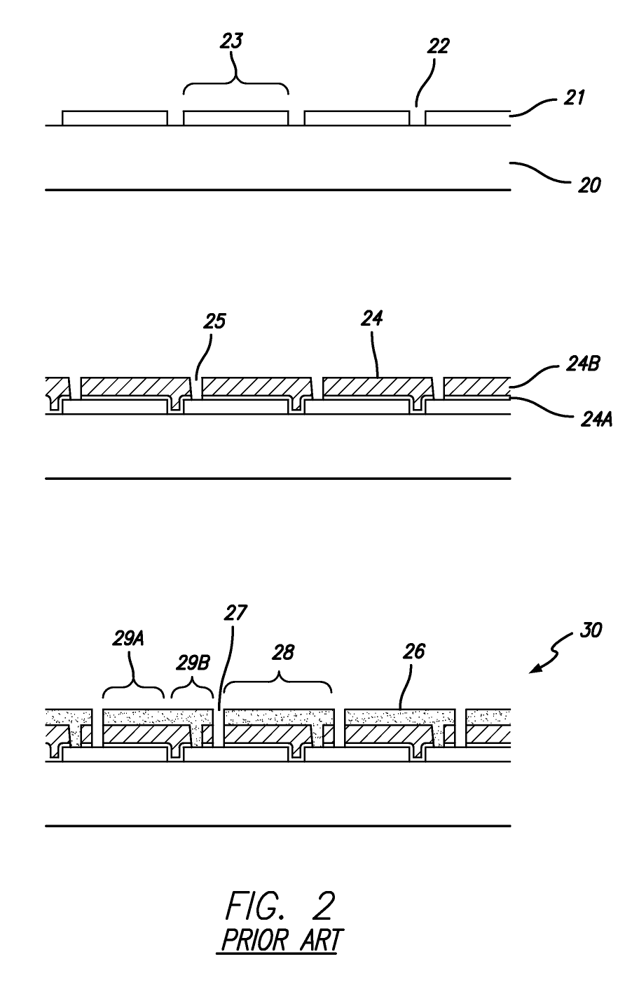

The process flow and the integrated module structure 31 described in FIGS. 3A, 3B and 3C have several benefits when compared with the process and structure described in FIG. 2. First of all, the present invention offers flexibility in the selection of the materials used for the formation of the first conductive layer 36 and the second conductive layer 38. For example, the criteria for the selection of a first material for the formation of the first conductive layer 36 may be the ability of the first material to make a good ohmic contact to the solar cell absorber layer 35B, but the criteria for the selection of a second material for the formation of the second conductive layer 38 may be the ability of the second material to make a good (e.g. low resistance and stable) ohmic contact to the transparent conductive material layer 32 at locations 39. Accordingly, the composition of the first material and the second material may be very different. In one embodiment the first material may comprise Mo, Ni, Ti, Cr, Co, Ta, Cu, and W, which make good ohmic contact to CdTe, whereas the second material may comprise Al, In and Sn, which do not make good stable ohmic contact to p-type CdTe absorber layers but make excellent ohmic contact to most transparent conductive layers.

In a second embodiment, the first conductive layer 36 may be a relatively low conductivity diffusion barrier layer that improves the stability of ohmic contact to the solar cell absorber layer 35B, whereas the second conductive layer 38 may comprise high conductivity metals making good ohmic contact to the transparent conductive material layer 32, without any concern for interdiffusion between the solar cell absorber layer 35B and the second conductive layer 38. Diffusion barrier materials that may be used for the formation of the first conductive layer 36 include, but are not limited to nitrides of Mo, W, Ti, Cr, Ta, V, Nb, Cu, Zr and Hf, and elements or alloys of Ru and Ir. For the case of metal nitrides, the bulk resistivity of these diffusion barrier materials may be relatively high, i.e. in the range of 0.001-100 ohm-cm, compared to the bulk resistivity of the metallic materials employed in the formation of the second conductive layer 38. It should be noted that the bulk resistivities of the metallic materials employed in the formation of the second conductive layer 38 may be in the range of 0.000001-0.0001 ohm-cm. The diffusion barrier materials slow down or totally prevent diffusion of the species in the second conductive layer 38 into the solar cell absorber layer 35B and vice versa, and thus improve the stability of the solar cell.

In another embodiment, the first conductive layer 36 may comprise a compound such as a semiconductor or inter-metallic material. Such materials include, but are not limited to metal tellurides, metal selenides, metal oxides, metal sulfides, metal phosphides, and their various alloys, amorphous or micro(nano)crystalline Si, amorphous or micro(nano)crystalline Ge and their various alloys with hydrogen or with each other.

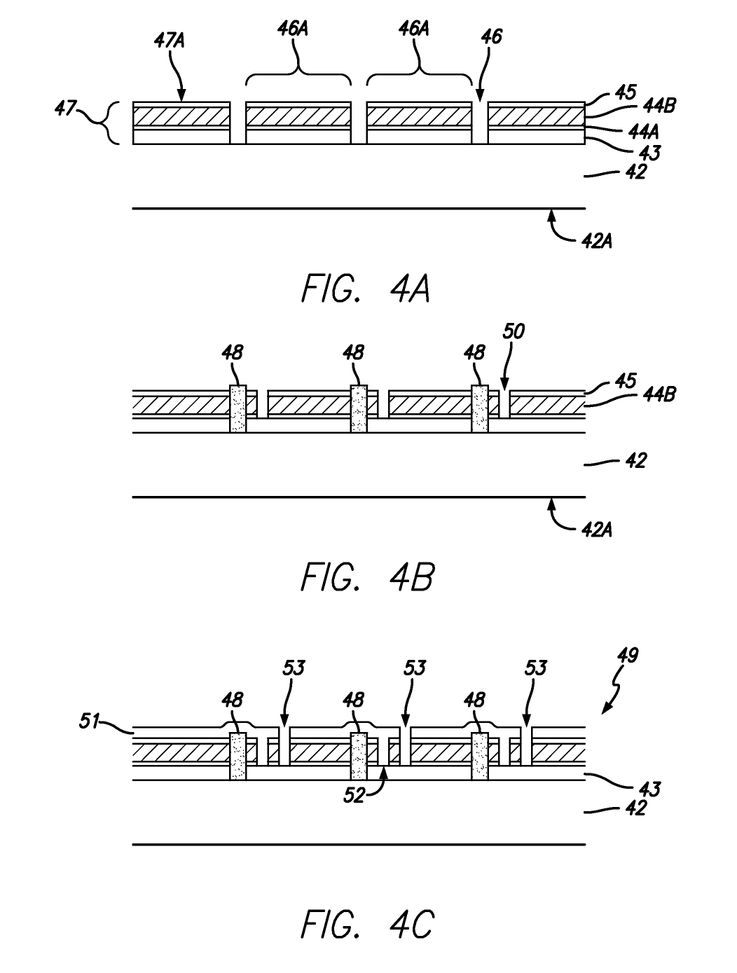

FIGS. 4A, 4B and 4C describe another preferred process flow to fabricate an integrated module structure 49 with the resulting structure shown in FIG. 4C. As shown in FIG. 4A, the first step of the process is the deposition of a transparent conductive film 43 on a transparent support sheet 42 which may be a sheet of glass or transparent polymeric material. A transparent junction formation layer 44A, a PV absorber layer 44B and a first conductive film 45 are then deposited over the transparent conductive film 43, forming a stack 47 as shown in FIG. 4A. A preferred material for the transparent junction formation layer 44A is CdS. A preferred material for the PV absorber layer 44B is a Group IIB-VIA compound film, more preferably a CdTe film. At this stage of the process a solar cell has been formed over the transparent support sheet 42 since the first conductive film 45 establishes a back ohmic contact to the PV absorber layer 44B. It should be noted that other well known process steps may be applied to the PV absorber layer 44B before the deposition of the first conductive film 45. These well known processes include annealing the PV absorber layer 44B in presence of Cl and/or in an oxygen containing environment, doping the exposed surface of the PV absorber layer 44B with a dopant such as Cu, and chemically etching the exposed surface of the PV absorber layer 44B. As shown in FIG. 4A, parallel cuts 46 are then made through the stack 47, preferably using laser scribing, forming stack strips 46A.

The next step in the process flow is filling the parallel cuts 46 with insulator plugs 48 as shown in FIG. 4B. Insulator plugs comprise a high resistivity material, preferably with resistivity values larger than 1000 ohm-cm. A preferred method of forming the insulator plugs 48 comprises the steps of coating the top surface 47A of the structure in FIG. 4A (including the top surface of the stack strips 46A and the parallel cuts 46) with a negative photoresist material, exposing the structure to a light flux entering from the bottom surface 42A of the transparent support sheet 42, and developing and rinsing the exposed photoresist. Since the light flux enters from the bottom surface 42A of the transparent support sheet 42, portions of the negative photoresist that are within the parallel cuts 46 get exposed and become insoluble plugs. The portions of the negative photoresist on the top surface of the stack strips, on the other hand, are shielded from light by the dark, and light absorbing, PV absorber layer 44B and the first conductive film 45. These unexposed portions of the photoresist get washed away during the developing and rinsing steps. This way the insulator plugs 48 comprising exposed and developed negative photoresist material are formed within the parallel cuts 46. Formation of photoresist plugs in solar cell structures has been described in a patent application by Bulent Basol (European Patent Application, Publication No: 0060487A1, incorporated herein by reference).

Referring back to FIG. 4B, after the formation of the insulating plugs 48, connection scribes 50 are formed through the first conductive film 45, the PV absorber layer 44B, and the transparent junction formation layer 44A, deep enough to expose a top surface of the transparent conductive film 43 along the bottom of the connection scribes 50. A second conductive film 51 is then deposited over the exposed surface as shown in FIG. 4C. The second conductive film 51 makes physical and electrical contact to top surface of the transparent conductive film 43 at the bottom of the connection scribes 50, at locations 52. The last step of the process flow to form the integrated module structure 49 is the formation of isolation lines or regions 53, which are formed by cutting through at least the second conductive film 51 and the first conductive film 45, and optionally also cutting through the PV absorber layer 44B, and again optionally, cutting through the transparent junction formation layer 44A. The isolation regions act as insulators and may be left unfilled or filled with an electrical insulator material.

The process flow and the module structure described through FIGS. 4A, 4B and 4C have all the benefits cited with respect to FIGS. 3A, 3B and 3C. The same materials mentioned above with respect to the composition of the first and second conductive films may also be used in the embodiment of FIGS. 4A-4C and for the same reasons as mentioned in connection with FIGS. 3A-3C. One additional benefit of the embodiment of FIGS. 4A-4C is the fact that the stack 47 comprising the transparent conductive film 43, the transparent junction formation layer 44A, the PV absorber layer 44B, and the first conductive film 45, is formed before any cuts or scribes are made in the stack 47. This way, the first conductive film 45 protects the whole device structure and especially the ohmic contact interface to the PV absorber layer 44B which is very sensitive. As described before the first conductive film 45 may comprise a diffusion barrier material such as a metal nitride or oxide. This diffusion barrier layer is a good protective cover for the whole device structure as the scribing steps and the deposition of the second conductive film 51 is carried out.

Although the present invention is described with respect to certain preferred embodiments, modifications thereto will be apparent to those skilled in the art.

Embodiments of the invention may be characterized as a method of forming a super-strate solar module structure comprising depositing a transparent conductive film on a front surface of a transparent support sheet so that light can enter the module structure through a back surface of the transparent support sheet, laying down a transparent junction formation layer, a photovoltaic absorber layer and a first conductive film over the transparent conductive film, thus forming a stack on the transparent support sheet, making parallel cuts in the stack, thus forming parallel stack strips separated by the parallel cuts, filling the parallel cuts with insulator plugs, providing openings next to the parallel cuts filled with insulator plugs, the openings exposing a top surface of the transparent conductive film in each parallel stack strip, and providing a second conductive film that covers the surface of the first conductive film, the insulator plugs and the exposed top surface of the transparent conductive film in each parallel stack strip. The first conductive film and the second conductive film may comprise different materials. The photovoltaic absorber layer may be a Group IIB-VIA compound. Further, the first conductive film may be a diffusion barrier material and may comprises at least one of a metal nitride and metal oxide. The second conductive film may be at least one of Sn, Al and In and the photovoltaic absorber layer may be, for example, CdTe. Filling the parallel cuts may use the steps of forming a layer of negative photoresist over the stack strips and the parallel cuts, exposing the layer of negative photoresist to a light flux coming through the back surface of the transparent support sheet, and developing and rinsing the exposed layer of negative photoresist. The first conductive film may be at least one of a metal nitride, a metal oxide, a metal selenide, a metal sulfide, a metal phosphide, amorphous Si and amorphous Ge. The photovoltaic absorber layer may be CdTe.

In accordance with other embodiments, the method of forming a super-strate thin film solar module structure may comprise depositing a transparent conductive material layer on a front surface of a transparent support so that light can enter the module structure through a back surface of the transparent support, forming scribe lines through the transparent conductive material layer, laying down a semiconductor window layer, a solar cell absorber layer and a first conductive layer over the transparent conductive material layer, making cuts through the first conductive layer, the solar cell absorber layer and the semiconductor window layer deep enough to expose a top surface of the transparent conductive material layer along the bottom of the cuts, and depositing a second conductive layer which makes physical and electrical contact to the transparent conductive material layer at the bottom of the cuts. The first conductive film and the second conductive film may comprise different materials. The photovoltaic absorber layer may be a Group IIB-VIA compound. The first conductive film comprises a diffusion barrier material. and may be at least one of a metal nitride and metal oxide. The second conductive film may comprises at least one of Sn, Al and In and the photovoltaic absorber layer may be CdTe. The first conductive film may be at least one of a metal nitride, a metal oxide, a metal selenide, a metal sulfide, a metal phosphide, amorphous Si and amorphous Ge. Further, the photovoltaic absorber layer may be CdTe.

In accordance with other embodiments of the invention, a solar module structure may include a transparent support sheet; a plurality of stack strips, each stack strip comprising: a transparent conductive layer disposed on the transparent support sheet; a transparent junction layer disposed on the transparent conductive layer; a photovoltaic absorber layer disposed on the transparent junction layer; a first conductive film disposed over the photovoltaic absorber layer;

a plurality of insulator plugs disposed between and separating adjacent ones of the plurality of stack strips, a second conductive film disposed on each of the plurality of stack strips making physical and electrical contact to the first conductive film and extending into at least one scribe, the at least one scribe extending at least partially into an adjacent stack strip so as to permit the second conductive film to make electrical contact to a top surface of the transparent conductive layer of the adjacent stack strip; and an isolation region formed within each of the plurality of stacks, the isolation region extending across a surface of the stack and extending to include at least the first and the second conductive films. In this structure, the first conductive film does not contact the transparent conductive layer. Further, the isolation region may extend to include the photovoltaic absorber layer within each stack. Alternately, the isolation region may extend to include the photovoltaic absorber layer and the transparent junction layer of each stack. The first conductive film may include a diffusion barrier material and the second conductive film may be different from the first conductive film. The first conductive film may be selected to make ohmic contact with photovoltaic absorber layer and the second conductive film may be selected to make ohmic contact with the transparent conductive layer. The photovoltaic absorber layer may comprises CdTe and the first conductive film may be selected from the group comprising Mo, Ni, Ti, Cr, Co, Ta, Cu, and W and their nitrides. The second conductive film may be selected from the group comprising Al, In and Sn. The photovoltaic absorber layer may be a Group IIB-VIA compound. The photovoltaic absorber layer may be CdTe and the first conductive film may be selected from the group comprising a metal oxide, a metal selenide, a metal sulfide, a metal phosphide, amorphous Si, nanocrystalline Si, amorphous Ge and nanocrystalline Ge.

In accordance with yet another embodiment of the invention, there is disclosed a solar module structure having a transparent support sheet; a plurality of stacks, each stack comprising: a transparent conductive layer disposed on the transparent support sheet; a transparent junction layer disposed on the transparent conductive layer; a photovoltaic absorber layer disposed on the transparent junction layer; a first conductive film disposed over the photovoltaic absorber layer. There is also provided a second conductive film disposed on each of the plurality of stacks making physical and electrical contact to the first conductive film and extending into at least one cut within each stack, the at least one cut extending at least partially into the stack so as to permit the second conductive film to make electrical contact to a top surface of the transparent conductive layer of an adjacent stack; and a plurality of isolation scribes disposed between adjacent ones of the plurality of stacks, the isolation scribes extending across a surface of the stack and extending to include at least the first and second conductive films. The first conductive film does not contact the transparent conductive layer. The isolation scribes may extend to include the photovoltaic absorber layer within each stack. Alternatively, the isolation scribes may extend to include the photovoltaic absorber layer and the transparent junction layer of each stack. The first conductive film may include a diffusion barrier material and the second conductive film may be different from the first conductive film. The first conductive film may be selected to make ohmic contact with photovoltaic absorber layer and the second conductive film may be selected to make ohmic contact with the transparent conductive layer. The photovoltaic absorber layer may comprises CdTe and the first conductive film may be selected from the group comprising Mo, Ni, Ti, Cr, Co, Ta, Cu, and W, and their nitrides. The second conductive film is selected from the group comprising Al, In and Sn. The photovoltaic absorber layer may be a Group IIB-VIA compound and the Group IIB-VI compound may be CdTe. The first conductive film may be selected from the group comprising a metal oxide, a metal selenide, a metal sulfide, a metal phosphide, amorphous Si, nanocrystalline Si, amorphous Ge and nanocrystalline Ge.

I claim:

1. A method of forming a super-strate solar module structure comprising the steps of;
depositing a transparent conductive film on a front surface of a transparent support sheet so that light can enter the module structure through a back surface of the transparent support sheet,
laying down a transparent junction formation layer, a photovoltaic absorber layer and a first conductive film over the transparent conductive film, thus forming a stack on the transparent support sheet,
making parallel cuts in the stack, thus forming parallel stack strips separated by the parallel cuts,
filling the parallel cuts with insulator plugs,
providing openings next to the parallel cuts filled with insulator plugs, the openings exposing a top surface of the transparent conductive film in each parallel stack strip,
providing a second conductive film that covers the surface of the first conductive film, the insulator plugs and the exposed top surface of the transparent conductive film in each parallel stack strip.

2. The method in claim 1 wherein the first conductive film and the second conductive film comprise different materials.

3. The method in claim 2 wherein the photovoltaic absorber layer is a Group IIB-VIA compound.

4. The method in claim 3 wherein the first conductive film comprises a diffusion barrier material.

5. The method in claim 4 wherein the diffusion barrier material comprises at least one of a metal nitride and metal oxide.

6. The method in claim 5 wherein the second conductive film comprises at least one of Sn, Al and In and the photovoltaic absorber layer is CdTe.

7. The method in claim 3 wherein the step of filling the parallel cuts comprises the steps of forming a layer of negative photoresist over the stack strips and the parallel cuts, exposing the layer of negative photoresist to a light flux coming through the back surface of the transparent support sheet, developing and rinsing the exposed layer of negative photoresist.

8. The method in claim 2 wherein the first conductive film comprises at least one of a metal nitride, a metal oxide, a metal selenide, a metal sulfide, a metal phosphide, amorphous Si and amorphous Ge.

9. The method in claim 8 wherein the photovoltaic absorber layer is CdTe.

10. A method of forming a super-strate thin film solar module structure comprising the steps of;
depositing a transparent conductive material layer on a front surface of a transparent support so that light can enter the module structure through a back surface of the transparent support,
forming scribe lines through the transparent conductive material layer,
laying down a semiconductor window layer, a solar cell absorber layer and a first conductive layer over the transparent conductive material layer,
making cuts through the first conductive layer, the solar cell absorber layer and the semiconductor window layer deep enough to expose a top surface of the transparent conductive material layer along the bottom of the cuts, and
depositing a second conductive layer which makes physical and electrical contact to the transparent conductive material layer at the bottom of the cuts.

11. The method in claim 10 wherein the first conductive film and the second conductive film comprise different materials.

12. The method in claim 11 wherein the photovoltaic absorber layer is a Group IIB-VIA compound.

13. The method in claim 12 wherein the first conductive film comprises a diffusion barrier material.

14. The method in claim 13 wherein the diffusion barrier material comprises at least one of a metal nitride and metal oxide.

15. The method in claim 14 wherein the second conductive film comprises at least one of Sn, Al and In and the photovoltaic absorber layer is CdTe.

16. The method in claim 11 wherein the first conductive film comprises at least one of a metal nitride, a metal oxide, a metal selenide, a metal sulfide, a metal phosphide, amorphous Si and amorphous Ge.

17. The method in claim 16 wherein the photovoltaic absorber layer is CdTe.

18. A solar module structure comprising:
a transparent support sheet;
a plurality of stack strips, each stack strip comprising:
a transparent conductive layer disposed on the transparent support sheet;
a transparent junction layer disposed on the transparent conductive layer;
a photovoltaic absorber layer disposed on the transparent junction layer;
a first conductive film disposed over the photovoltaic absorber layer;
a plurality of insulator plugs disposed between and separating adjacent ones of the plurality of stack strips
a second conductive film disposed on each of the plurality of stack strips making physical and electrical contact to the first conductive film and extending into at least one scribe, the at least one scribe extending at least partially into an adjacent stack strip so as to permit the second conductive film to make electrical contact to a top surface of the transparent conductive layer of the adjacent stack strip; and
an isolation region formed within each of the plurality of stacks, the isolation region extending across a surface of the stack and extending to include at least the first and the second conductive films,
wherein the first conductive film does not contact the transparent conductive layer.

19. The solar module structure as recited in claim 18, wherein the isolation region extends to include the photovoltaic absorber layer within each stack.

20. The solar module structure as recited in claim 18, wherein the isolation region extends to include the photovoltaic absorber layer and the transparent junction layer of each stack.

21. The solar module structure as recited in claim 18, wherein the first conductive film comprises a diffusion barrier material and the second conductive film is different from the first conductive film.

22. The solar module structure as recited in claim 18, wherein the first conductive film is selected to make ohmic contact with photovoltaic absorber layer and the second conductive film is selected to make ohmic contact with the transparent conductive layer.

23. The solar module structure as recited in claim 18 wherein the photovoltaic absorber layer comprises CdTe and the first conductive film is selected from the group comprising Mo, Ni, Ti, Cr, Co, Ta, Cu, and W and their nitrides.

24. The solar module structure as recited in claim 23 wherein the second conductive film is selected from the group comprising Al, In and Sn.

25. The solar module structure as recited in claim 18, wherein the photovoltaic absorber layer is a Group IIB-VIA compound.

26. The solar module structure as recited in claim 18 wherein the photovoltaic absorber layer comprises CdTe and the first conductive film is selected from the group comprising a metal oxide, a metal selenide, a metal sulfide, a metal phosphide, amorphous Si, nanocrystalline Si, amorphous Ge and nanocrystalline Ge.

27. A solar module structure comprising:
a transparent support sheet;
a plurality of stacks, each stack comprising:
a transparent conductive layer disposed on the transparent support sheet;
a transparent junction layer disposed on the transparent conductive layer;
a photovoltaic absorber layer disposed on the transparent junction layer;
a first conductive film disposed over the photovoltaic absorber layer;
a second conductive film disposed on each of the plurality of stacks making physical and electrical contact to the first conductive film and extending into at least one cut within each stack, the at least one cut extending at least partially into the stack so as to permit the second conductive film to make electrical contact to a top surface of the transparent conductive layer of an adjacent stack; and
a plurality of isolation scribes disposed between adjacent ones of the plurality of stacks, the isolation scribes extending across a surface of the stack and extending to include at least the first and second conductive films, wherein,
the first conductive film does not contact the transparent conductive layer.

28. The solar module structure as recited in claim 27, wherein the isolation scribes extend to include the photovoltaic absorber layer within each stack.

29. The solar module structure as recited in claim 27, wherein the isolation scribes extend to include the photovoltaic absorber layer and the transparent junction layer of each stack.

30. The solar module structure as recited in claim 27, wherein the first conductive film comprises a diffusion barrier material and the second conductive film is different from the first conductive film.

31. The solar module structure as recited in claim 27, wherein the first conductive film is selected to make ohmic contact with photovoltaic absorber layer and the second conductive film is selected to make ohmic contact with the transparent conductive layer.

32. The solar module structure as recited in claim 27 wherein the photovoltaic absorber layer comprises CdTe and the first conductive film is selected from the group comprising Mo, Ni, Ti, Cr, Co, Ta, Cu, and W, and their nitrides.

33. The solar module structure as recited in claim 32, wherein the second conductive film is selected from the group comprising Al, In and Sn.

34. The solar module structure as recited in claim 27 wherein the photovoltaic absorber layer is a Group IIB-VIA compound.

35. The solar module structure as recited in claim 34 wherein the Group IIB-VI compound is CdTe and the first conductive film is selected from the group comprising a metal oxide, a metal selenide, a metal sulfide, a metal phosphide, amorphous Si, nanocrystalline Si, amorphous Ge and nanocrystalline Ge.
